(19) United States
(12) Patent Application Publication
(10) Pub. No.: US 2009/0108853 A1
(43) Pub. Date: Apr. 30, 2009

(54) MEASUREMENT APPARATUS AND MEASUREMENT METHOD

(75) Inventors: Minoru Yuyama, Yokohama-shi (JP); Hiroyuki IIZUKA, Yokohama-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ONO SOKKI CO., LTD., Yokohama-shi (JP)

(21) Appl. No.: 12/256,192

(22) Filed: Oct. 22, 2008

(30) Foreign Application Priority Data
Oct. 26, 2007 (JP) 2007-278641

(51) Int. Cl. G01B 7/06; G01R 27/26

(52) U.S. Cl. 324/686

(57) ABSTRACT

There are provided a measurement apparatus and a measurement method capable of stably measuring the physical quantity involved in a measurement object. Two or more electrostatic capacity type displacement sensing devices are mutually connected in their earths and apply to the measuring heads carrier signals each including a sinusoidal wave of a same frequency wherein a sum total of phases becomes 0°, respectively, so that a thickness of the measurement object is measured.

### BACKGROUND OF THE INVENTION

1. Field of the Invention

The present invention relates to a measurement apparatus and a measurement method for and of measuring the physical quantity involved in a measurement object in accordance with two or more electrostatic capacities determined by two or more electrostatic capacity type displacement sensing devices.

2. Description of the Related Art

Hitherto, there is known an electrostatic capacity type displacement sensing device having a measuring head that is arranged at the position opposed to a measurement object, which the electrostatic capacity type displacement sensing device outputs the physical quantity such as voltage corresponding to the electrostatic capacity between the measurement object and the measuring head, wherein the physical quantity changes in proportion to the distance between the measurement object and the measuring head.

For instance, Japanese Patent Application Publication No. H9-280806 discloses an electrostatic capacity type displacement sensing device capable of outputting physical quantity corresponding to electrostatic capacity with great accuracy and stability, even if the electrostatic capacity between a measurement object and a sensor electrode is slight, in such a manner that AC signal, which is controlled in amplitude, is applied to a sensor electrode that is a measuring head.

Moreover, for instance, Japanese Patent Application Publication No. 2004-354270 discloses an electrostatic capacity type displacement sensing device having an operational amplifier to which a signal representative of electrostatic capacity from a measuring head is input, and a low-pass filter to which an output signal from the operational amplifier is input, which electrostatic capacity type displacement sensing device is capable of outputting physical quantity corresponding to electrostatic capacity with great accuracy and stability in such a manner that the noise that mixes in the band of the low-pass filter is prevented.

Now, there is known a measurement apparatus for measuring the physical quantity involved in a measurement object in accordance with two or more electrostatic capacities determined by two or more electrostatic capacity type displacement sensing devices. There is a thickness measurement apparatus in one of such the measurement apparatus. According to such a measurement apparatus, the measuring heads of two electrostatic capacity type displacement sensing devices are disposed to mutually oppose, and the measurement object is arranged between both the measuring heads, so that the thickness of the measurement object is measured in accordance with two physical quantities output from these two electrostatic capacity type displacement sensing devices. According to this thickness measurement apparatus, the measurement object is interposed and measured between two electrostatic capacity type displacement sensing devices. Thus, it is possible to measure accurately the thickness of the measurement object, even if the measurement object curves and undulates.

FIG. 1 is a view showing a structure of the conventional thickness measurement apparatus.

A thickness measurement apparatus 100 shown in FIG. 1 is provided with a first electrostatic capacity type displacement sensing device 110, a second electrostatic capacity type displacement sensing device 120, and a thickness computing section 100_1. The first electrostatic capacity type displacement sensing device 110 has an electrostatic capacity conversion section 111 and an electrostatic capacity type displacement sensor 112. The electrostatic capacity conversion section 111 is connected with the electrostatic capacity type displacement sensor 112 through a cable 113. The second electrostatic capacity type displacement sensing device 120 has an electrostatic capacity conversion section 121 and an electrostatic capacity type displacement sensor 122. The electrostatic capacity conversion section 121 is connected with the electrostatic capacity type displacement sensor 122 through a cable 123.

Individual earth of the electrostatic capacity conversion sections 111 and 121 is mutually connected with a lead and connected with a measurement object 30.

The electrostatic capacity type displacement sensors 112 and 122 are arranged so as to mutually oppose, and the measurement object 30 is arranged between these electrostatic capacity type displacement sensors 112 and 122. There are a conductor and a semiconductor as the measurement object 30.

The electrostatic capacity conversion sections 111 and 121 convert the electrostatic capacities detected with the electrostatic capacity type displacement sensors 112 and 122 into voltages that are the physical quantity, respectively, and generate output voltages E10 and E20 proportional to the distance between the measurement object 30 and the electrostatic capacity type displacement sensors 112 and 122, respectively. These output voltages E10 and E20 are input to the thickness computing section 100_1.

A distance (D) between electrostatic capacity type displacement sensors 112 and 122 is computed from an total (D=t+GAP−112+GAP−122) of each distance and already-known thickness t of the measurement object 30, where the measurement object 30 having already-known thickness t is arranged, and the distance between the measurement object 30 and individual one of the electrostatic capacity type displacement sensors 112 and 122 is measured, and the value is assumed to be GAP−112 and GAP−122. The thickness computing section 100_1 stores therein a reference voltage associated with the distance (D). When the measurement object 30 is measured, the thickness computing section 100_1 outputs a signal α representative of the thickness by the subtraction of the voltage values represented by the voltages E₁₀ and E₂₀ corresponding to the outputs of the electrostatic capacity type displacement sensors 112 and 122 from the reference value corresponding to the distance (D). Thus, the thickness measurement apparatus 100 measures the thickness of the measurement object 30.

In the thickness measurement apparatus 100 as mentioned above, in order to measure the thickness of the measurement object 30 with stability, there is a need that the earth of the electrostatic capacity conversion sections 111 and 121 and the measurement object 30 are given with the common potential (direct current voltage DC0V). In order that the earths of electrostatic capacity conversion sections 111 and 121 is provided with the common potential, it is effective that the earths of electrostatic capacity conversion sections 111 and 121 are connected with the lead, as mentioned above, and therefore it is easy to implement the common potential for the electrostatic capacity conversion sections 111 and 121.

However, there are the following problems when the measurement object 30 and the earths of the electrostatic capacity conversion sections 111 and 121 are made the common potential.

For instance, when the measurement object 30 is concerned with the product such as the silicon wafers, it may happen that the measurement object 30 wants to avoid contact with the lead. Moreover, because of saving the time of the measurement, there often happens a case where it is difficult to take a direct conduction with the electrostatic capacity conversion sections 111 and 121. Therefore, for instance, there is made such a device that there is provided a metallic measurement stand, and the measurement object 30 is put on the metallic measurement stand so as to take a conduction. On the other hand, in the event that it is not desired that the measurement object 30 is in contact with the metal of the measurement stand, there is made such a device that the resin finishing and the like is applied to the surface of the measurement stand. Here, when the resin on the surface of the measurement stand is thinned as much as possible or there are warp and distortion on the measurement object and it is not smooth, it is necessary to install the vacuum mechanism and to construct a system that makes the measurement object adsorb on a plinth.

In the event that it is difficult to make a potential between the measurement object 30 and earths of the electrostatic capacity conversion sections 111 and 121 to the same potential, impedance is caused between the measurement object 30 and earths of the electrostatic capacity conversion sections 111 and 121. The error of measurement occurs because the carrier current from the electrostatic capacity conversion sections 111 and 121 flows to the impedance. Moreover, the change occurs in the impedance in accordance with the measurement environment, and the measurement becomes unstable.

Therefore, when the thickness of the measurement object 30 is measured by using 2 electrostatic capacity type displacement sensing devices 110 and 120 and a thickness computing section 100_1, the current that flows to the impedance might be comparatively large, and it is difficult to perform a steady measurement because the impedance changes in accordance with the measurement environment.

### SUMMARY OF THE INVENTION

In view of the foregoing, it is an object of the present invention to provide a measurement apparatus and a measurement method capable of stably measuring the physical quantity involved in a measurement object.

To achieve the above-mentioned objects, the present invention provides a measurement apparatus that measures a physical quantity involved in a measurement object in accordance with two or more electrostatic capacities determined by two or more electrostatic capacity type displacement sensing devices, where each of the two or more electrostatic capacity type displacement sensing devices has a measuring head to be arranged at a position opposed to the measurement object and determines an electrostatic capacity between the measurement object and the measuring head which electrostatic capacity changes according to a distance between the measurement object and the measuring head, and the measuring heads of the electrostatic capacity type displacement sensing devices are arranged opposing to the measurement object,

wherein the two or more electrostatic capacity type displacement sensing devices are mutually connected in their earths and apply to the measuring heads carrier signals each including a sinusoidal wave of a same frequency wherein a sum total of phases becomes 0°, respectively.

FIG. 2 is a view showing an equivalent circuit useful for understanding a principle of a measurement apparatus of the present invention.

Incidentally, it explains for the sake of convenience here with the example of two electrostatic capacity type displacement sensing devices as two or more electrostatic capacity type displacement sensing devices of the present invention.

Electric capacity C₁ₓ shown in FIG. 2 is a first electric capacity between a first measuring head and a measurement object that composes a first electrostatic capacity type displacement sensing device of two electrostatic capacity type displacement sensing devices. Electric capacity C₂ₓ is a second electric capacity between a second measuring head and a measurement object that composes the second electrostatic capacity type displacement sensing device of two electrostatic capacity type displacement sensing devices. Impedance Z is impedance between a measurement object and earths of 2 electrostatic capacity type displacement sensing devices.

Shown in the equivalent circuit of FIG. 2 are carrier signals E₁ₛ and E₂ₛ of first and second electrostatic capacity type displacement sensing devices, electric capacities C₁ₛ and C₂ₛ of the standard capacitors, and amplifiers (both gain G=1) that composes the first and second electrostatic capacity type displacement sensing devices.

Output voltages E₁₀ and E₂₀ are expressed by the following equations.

$$\begin{matrix}{E}_{1 O} = Z ( \frac{{E}_{1 S}}{{Z}_{1 S}} + \frac{{E}_{2 S}}{{Z}_{2 S}} ) + {d}_{1 X} \frac{{C}_{1 S} {E}_{1 S}}{ɛ {S}_{1 X}} & ( 1 ) \\ {E}_{2 O} = Z ( \frac{{E}_{1 S}}{{Z}_{1 S}} + \frac{{E}_{2 S}}{{Z}_{2 S}} ) + {d}_{2 X} \frac{{C}_{2 S} {E}_{2 S}}{ɛ {S}_{2 X}} & ( 2 )\end{matrix}$$

Here,

Z_{1S}=1/ωC_{1S},Z_{2S}=1/ωC_{2S} (3)

Z_{1X}=1/ωC_{1X}=d_{1X}/ωεS_{1X},Z_{2X}=1/ωC_{1X}=d_{2X}/ωεS_{2X} (4)

Where d₁ₓ and d₂ₓ denote inter-electrode gaps of C₁ₓ and C₂ₓ (distances between 1st and 2nd measuring heads and the measurement object), respectively, S₁ₓ and S₂ₓ denote electrode areas of C₁ₓ and C₂ₓ, respectively, and ε is a permittivity.

In the equations (1) and (2), when the following equation (5) is given,

$$Z ( \frac{{E}_{1 S}}{{Z}_{1 S}} + \frac{{E}_{2 S}}{{Z}_{2 S}} ) = 0 \qquad ( 5 )$$

the output voltages E₁₀ and E₂₀ can be proportional to the distances between the 1st and 2nd measuring heads and the measurement object, respectively.

According to the prior art, impedance Z is brought close to 0. On the other hand, according to the present invention, equation (6) involved in the impedance Z is given by the following equation.

$$\frac{{E}_{1 S}}{{Z}_{1 S}} + \frac{{E}_{2 S}}{{Z}_{2 S}} = 0 \qquad ( 6 )$$

That is, applied to the 1st and 2nd measuring heads are carrier signals each having a sine wave of same frequency wherein a sum total of phases becomes 0°, respectively. Accordingly, it is assumed that E₂ₛ=−E₁ₛ, Z₂ₛ=Z₁ₛ. Thus, even if there occur impedances between the measurement object and earths of two electrostatic capacity type displacement sensing devices, the carrier signals become mutually negative. As a result, no carrier currents flow to the impedance. Thus, the thickness measurement apparatus is independent of the impedance between the measurement object and earths of two electrostatic capacity type displacement sensing devices, so that the measurement result can be proportional to the distance between the measurement object and the 1st and 2nd measuring heads, that is, the displacement. Therefore, it is possible to measure the physical quantity involved in the measurement object with stability.

In the measurement apparatus according to the present invention as mentioned above, it is preferable that the measurement apparatus is a thickness measurement apparatus in which the measuring heads of two electrostatic capacity type displacement sensing devices are arranged opposing to one another, and the measurement object is disposed between both the measuring heads so that a thickness of the measurement object is measured in accordance with the two electrostatic capacities determined by the two electrostatic capacity type displacement sensing devices.

According to the thickness measurement apparatus as mentioned above, it is possible to measure the thickness of the measurement object with stability.

In the measurement apparatus according to the present invention as mentioned above, it is preferable that the measurement apparatus is a rotation body measurement apparatus in which the measuring heads of two or more electrostatic capacity type displacement sensing devices are arranged opposing to a rotation body that is the measurement object, and the physical quantity of the rotation body is measured in accordance with the two or more electrostatic capacities determined by the two or more electrostatic capacity type displacement sensing devices.

According to the rotor measurement apparatus as mentioned above, it is possible to measure the eccentricity, the roundness, the vibration, the irregularity and the like, which are physical quantity of the rotation body, with stability.

In the measurement apparatus according to the present invention as mentioned above, it is preferable that the measurement apparatus is a vibration body measurement apparatus in which the measuring heads of two or more electrostatic capacity type displacement sensing devices are arranged opposing to a vibration body that is the measurement object, and a vibration of the vibration body is measured in accordance with the two or more electrostatic capacities determined by the two or more electrostatic capacity type displacement sensing devices.

According to the vibration body measurement apparatus as mentioned above, it is possible to measure the vibration of the vibration body with stability, and thus it is possible to analyze the deformation of the vibration body with accuracy.

To achieve the above-mentioned objects, the present invention provides a measurement method of measuring physical quantity involved in a measurement object, the measurement method including the steps of:

preparing two or more electrostatic capacity type displacement sensing devices each of which has a measuring head that to be arranged at a position opposed to the measurement object, and which determine an electrostatic capacity between the measurement object and the measuring head which electrostatic capacity changes according to a distance between the measurement object and the measuring head;

arranging the measuring heads of the electrostatic capacity type displacement sensing devices as being opposed to the measurement object;

mutually connecting two or more electrostatic capacity type displacement sensing devices in their earths and applying to the measuring heads carrier signals each including a sinusoidal wave of a same frequency wherein a sum total of phases becomes 0°, respectively, so that electrostatic capacities are measured using the two or more electrostatic capacity type displacement sensing devices; and

determining a physical quantity involved in the measurement object in accordance with the two or more electrostatic capacities determined by the two or more electrostatic capacity type displacement sensing devices.

According to the measurement method of the present invention, characterized by arranging the measuring heads of the electrostatic capacity type displacement sensing devices opposing to the measurement object, and mutually connecting two or more electrostatic capacity type displacement sensing devices in their earths and applying to the measuring heads carrier signals each having a sine wave of same frequency wherein a sum total of phases becomes 0°, respectively, so that electrostatic capacities are measured using the two or more electrostatic capacity type displacement sensing devices. Thus, even if there occur impedances between the measurement object and earths of two or more electrostatic capacity type displacement sensing devices, the carrier signals become mutually negative. As a result, no carrier currents flow to the impedance. Thus, the measurement apparatus is independent of the impedance between the measurement object and earths of two or more electrostatic capacity type displacement sensing devices, so that the measurement result can be proportional to the distance between the measurement object and two or more measuring heads, that is, the displacement. Therefore, it is possible to measure the physical quantity involved in the measurement object with stability.

In the measurement method according to the present invention as mentioned above, it is preferable that the measurement method is a thickness measurement method in which the measuring heads of two electrostatic capacity type displacement sensing devices are arranged opposing to one another, and the measurement object is disposed between both the measuring heads so that a thickness of the measurement object is measured in accordance with the two electrostatic capacities determined by the two electrostatic capacity type displacement sensing devices.

According to the measurement method as mentioned above, it is possible to measure the thickness of the measurement object with stability.

In the measurement method according to the present invention as mentioned above, it is preferable that the measurement method is a rotation body measurement method in which the measuring heads of two or more electrostatic capacity type displacement sensing devices are arranged opposing to a rotation body that is the measurement object, and the physical quantity of the rotation body is measured in accordance with the two or more electrostatic capacities determined by the two or more electrostatic capacity type displacement sensing devices.

According to the rotor measurement method as mentioned above, it is possible to measure the eccentricity, the roundness, the vibration, the irregularity and the like, which are physical quantity of the rotation body, with stability.

In the measurement method according to the present invention as mentioned above, it is preferable that the measurement method is a vibration body measurement method in which the measuring heads of two or more electrostatic capacity type displacement sensing devices are arranged opposing to a vibration body that is the measurement object, and a vibration of the vibration body is measured in accordance with the two or more electrostatic capacities determined by the two or more electrostatic capacity type displacement sensing devices.

According to the thickness measurement method as mentioned above, it is possible to measure the vibration of the vibration body with stability, and thus it is possible to analyze the deformation of the vibration body with accuracy.

### BRIEF DESCRIPTION OF THE DRAWINGS

FIG. 1 is a view showing a structure of the conventional thickness measurement apparatus.

FIG. 2 is a view showing an equivalent circuit useful for understanding a principle of a measurement apparatus of the present invention.

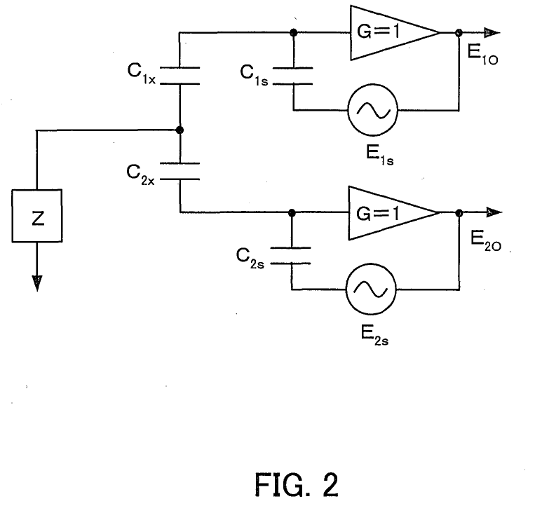

FIG. 3 is a schematic construction view of a thickness measurement apparatus according to a first embodiment of a measurement apparatus of the present invention.

FIG. 4 is a view showing an equivalent circuit of the thickness measurement apparatus shown in FIG. 3.

FIG. 5 is a schematic construction view of a rotor measurement apparatus according to a second embodiment of a measurement apparatus of the present invention.

FIG. 6 is a schematic construction view of a vibration body measurement apparatus according to a third embodiment of a measurement apparatus of the present invention.

FIG. 7 is a view showing an equivalent circuit showing a thickness measurement apparatus according to a fourth embodiment of a measurement apparatus of the present invention.

### DETAILED DESCRIPTION OF PREFERRED EMBODIMENTS

Embodiments of the present invention will be described with reference to the accompanying drawings.

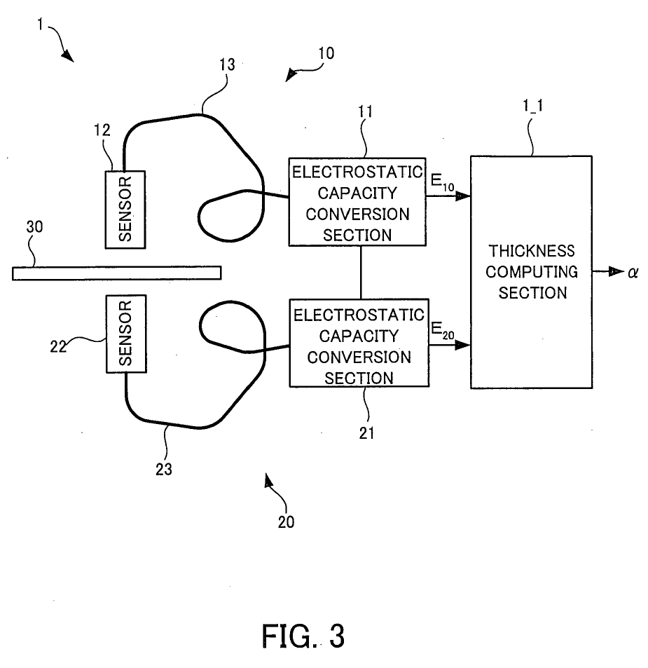

FIG. 3 is a schematic construction view of a thickness measurement apparatus according to a first embodiment of a measurement apparatus of the present invention.

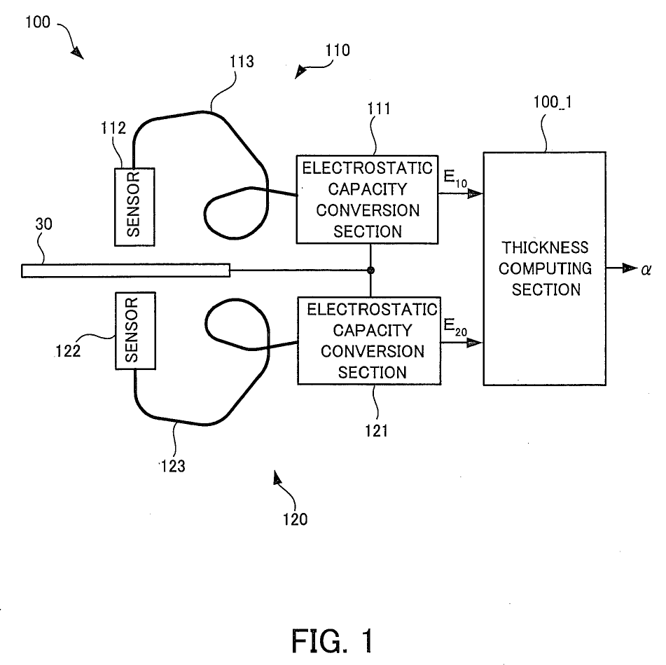

Incidentally, a first embodiment of a measurement method of the present invention is applied to a thickness measurement apparatus 1 shown in FIG. 1. The thickness measurement apparatus 1 comprises a first electrostatic capacity type displacement sensing device 10, a second electrostatic capacity type displacement sensing device 20, and a thickness computing section 1_1. The first electrostatic capacity type displacement sensing device 10 and the second electrostatic capacity type displacement sensing device 20 correspond to an example of two or more electrostatic capacity type displacement sensing devices referred to in the present invention.

The first electrostatic capacity type displacement sensing device 10 has an electrostatic capacity conversion section 11 and an electrostatic capacity type displacement sensor 12 (it corresponds to an example of the measuring head referred to in the present invention). The electrostatic capacity conversion section 11 is connected with the electrostatic capacity type displacement sensor 12 by a cable 13.

The second electrostatic capacity type displacement sensing device 20 has an electrostatic capacity conversion section 21 and an electrostatic capacity type displacement sensor 22 (it corresponds to an example of the measuring head referred to in the present invention). The electrostatic capacity conversion section 21 is connected with the electrostatic capacity type displacement sensor 22 by a cable 23.

The earths of the electrostatic capacity conversion section 11 and the electrostatic capacity conversion section 21 are connected to one another by a lead.

The electrostatic capacity type displacement sensors 12 and 22 are arranged so as to mutually oppose, and the measurement object 30 is arranged between these electrostatic capacity type displacement sensors 12 and 22. There are a conductor and a semiconductor as the measurement object 30.

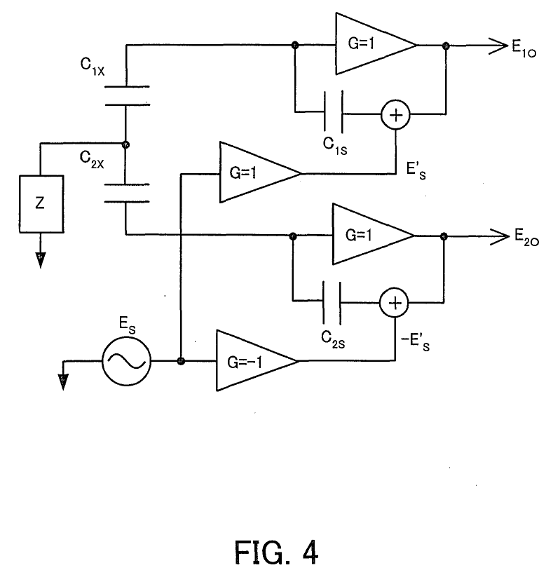

To measure the thickness of the measurement object 30 with the thickness measurement apparatus 1, the electrostatic capacity conversion sections 11 and 21 apply to the electrostatic capacity type displacement sensors 12 and 22 carrier signals each having a sine wave of same frequency wherein the sum total of the phase becomes 0°, respectively. More in detail, the electrostatic capacity conversion sections 11 and 21 obtain two carrier signals in which the phase is 180° mutually different from a common alternating-current power, and apply the carrier signals to the electrostatic capacity type displacement sensor 12 and 22, respectively. Hereinafter, there will be explained the details in conjunction with FIG. 4.

FIG. 4 is a view showing an equivalent circuit of the thickness measurement apparatus shown in FIG. 3.

Incidentally, it is noted that an equivalent circuit of the thickness computing section 1_1 shown in FIG. 3 is not illustrated.

The equivalent circuit shown in FIG. 4 shows an electrostatic capacity C₁ₓ between the measurement object 30 and the electrostatic capacity type displacement sensor 12 composing the thickness measurement apparatus 1 shown in FIG. 3. Further, it shows an electrostatic capacity C₂ₓ between the measurement object 30 and the electrostatic capacity type displacement sensor 22. Furthermore, it shows impedance (resistance) which is inserted between a node of the electrostatic capacity C₁ₓ and the electrostatic capacity C₂ₓ and the ground.

Still further, the equivalent circuit shown in FIG. 4 shows two mixers to which two carrier signals E's and −E's, which are mutually different in phase by 180°, are input from alternating-current power Eₛ through amplifiers (gain G=1, −1) of the insides of the electrostatic capacity conversion sections 11 and 21, respectively, electric capacities C₁ₛ and C₂ₛ of a standard capacitor of the insides of the electrostatic capacity conversion sections 11 and 21, and amplifiers (both gain G=1) of the insides of the electrostatic capacity conversion sections 11 and 21.

Still furthermore, the equivalent circuit shown in FIG. 4 shows output voltages E₁₀ and E₂₀ generated from the electrostatic capacity conversion sections 11 and 21 shown in FIG. 3, respectively.

The output voltages E₁₀ and E₂₀ are expressed by the following equations.

$$\begin{matrix}{E}_{1 O} = {d}_{1 X} \frac{{C}_{1 S} {E}_{S}^{′}}{ɛ {S}_{1 X}} & ( 7 ) \\ {E}_{2 O} = - {d}_{2 X} \frac{{C}_{2 S} {E}_{S}^{′}}{ɛ {S}_{2 X}} & ( 8 )\end{matrix}$$

Where d₁ₓ and d₂ₓ denote the inter-electrode gaps of C₁ₓ and C₂ₓ (distances of electrostatic capacity type displacement sensors 12 and 22 and the measurement object 30, respectively), respectively. Moreover, S₁ₓ and S₂ₓ denote the areas of the electrodes of C₁ₓ and C₂ₓ, respectively, and ε denotes permittivity.

The output voltages E₁₀ and E₂₀ are input to the thickness computing section 1_1 shown in FIG. 3.

The distance (D) between the electrostatic capacity type displacement sensors 12 and 22 is from an total (D=t+GAP−12+GAP−22) of each distance and already-known thickness t of the measurement object 30, where the measurement object 30 having already-known thickness t is arranged, and the distance between the measurement object 30 and individual one of the electrostatic capacity type displacement sensors 12 and 22 is measured, and the value is assumed to be GAP−112 and GAP−122. The thickness computing section 1_1 stores therein a reference voltage associated with the distance (D). When the measurement object 30 is measured, the thickness computing section 1_1 outputs a signal α representative of the thickness by the subtraction of the voltage values represented by the voltages E₁₀ and E₂₀ corresponding to the outputs of the electrostatic capacity type displacement sensors 12 and 22 from the reference value corresponding to the distance (D). Thus, the thickness measurement apparatus 1 measures the thickness of the measurement object 30.

As mentioned above, according to the thickness measurement apparatus 1 of the first embodiment of the present invention, the same frequency of sine wave carrier signals E′ₛ and −E′ₛ, which are mutually different in phase by 180°, are applied to the electrostatic capacity type displacement sensors 12 and 22, respectively. Therefore, even if there occur impedances between the measurement object 30 and earths of the electrostatic capacity conversion sections 11 and 21, the carrier signals E′ₛ and −E′ₛ become mutually negative. As a result, no carrier currents flow from the electrostatic capacity conversion sections 11 and 21 to the impedance. Thus, the thickness measurement apparatus 1 is independent of the impedance between the measurement object 30 and earths of the electrostatic capacity conversion sections 11 and 21, so that the measurement result can be proportional to the distance between the measurement object 30 and the electrostatic capacity conversion sections 11 and 21, that is, the displacement. Therefore, it is possible to measure the thickness of the measurement object 30 with stability.

Here, there will be explained the difference between the conventional method according to the actual measurement and the method of the invention (the first embodiment) referring to Table 1.

Table 1 shows the conventional method according to the actual measurement and the method of the present invention.

TABLE 1

Thickness (μm)

| Z(MΩ) | Conventional method | Present invention |
|---|---|---|
| 0 | 500 | 500 |
| 1 | 470 | 500 |
| Almost | Immeasurable | 500 |
| infinity | | |

Here, there will be shown a difference in the measurement result between the conventional method (FIG. 1) and the method according to the present invention (FIG. 3) wherein impedance Z between the measurement object and the earth changes, taking as an example of the thickness measurement of a metallic board of 500 μm in thickness. Thickness (μm) is a value in which the distance (displacement value) between two electrostatic capacity type displacement sensors and the measurement object is subtracted from the distance between the electrostatic capacity type displacement sensors. Resistance is inserted between the measurement object and the earth as impedance Z, and the thickness is measured where the impedance is changed as 0 MΩ, 1 MΩ, and almost infinity. According to the conventional method, as impedance Z becomes large, the measurement result (thickness) becomes small, and it becomes an incapable measurement in almost infinity. More in detail, when impedance Z is 0 MΩ, thickness is 500 μm, when impedance Z is 1 MΩ, thickness is 470 μm, and when impedance Z is almost infinity, it becomes an incapable measurement. To the contrary, according to the method according to the present invention, even if impedance Z is changed as 0 MΩ, 1 MΩ, and almost infinity, thickness is 500 μm in all and there is seen no change in the measurement result, and a steady measurement is able to be implemented. Therefore, it is possible to confirm effectiveness in the first embodiment of the present invention.

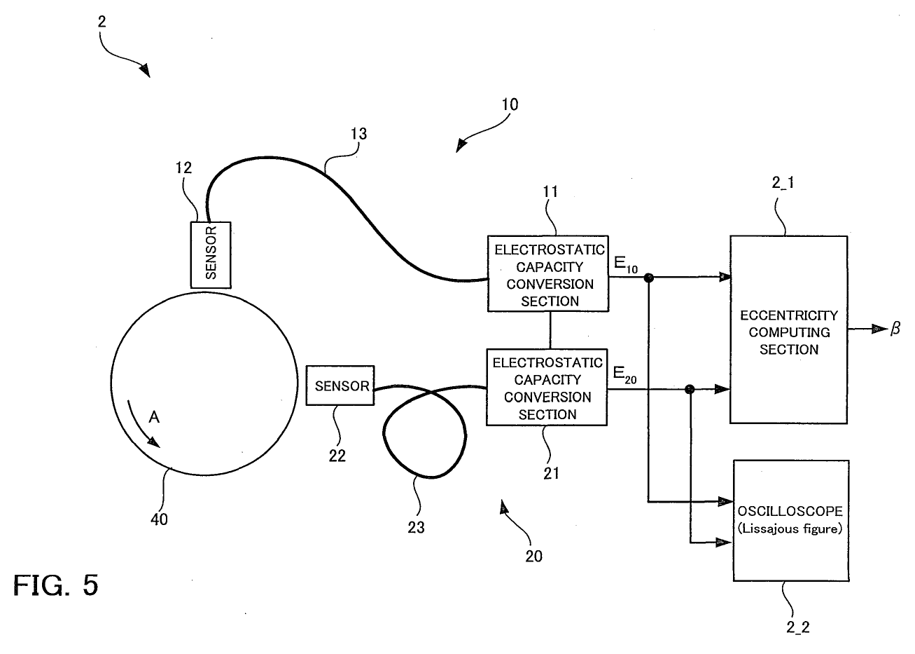

FIG. 5 is a schematic construction view of a rotor measurement apparatus according to a second embodiment of a measurement apparatus of the present invention.

In FIG. 5, the same parts are denoted by the same reference numbers as those of the thickness measurement apparatus 1 shown in FIG. 3.

A rotor measurement apparatus 2 shown in FIG. 5 comprises the first electrostatic capacity type displacement sensing device 10, the second electrostatic capacity type displacement sensing device 20, an eccentricity computing section 2_1 and an oscilloscope 2_2.

The first electrostatic capacity type displacement sensing device 10 has the electrostatic capacity conversion section 11 and the electrostatic capacity type displacement sensor 12. The electrostatic capacity conversion section 11 is connected with the electrostatic capacity type displacement sensor 12 by the cable 13.

The second electrostatic capacity type displacement sensing device 20 has the electrostatic capacity conversion section 21 and the electrostatic capacity type displacement sensor 22. The electrostatic capacity conversion section 21 is connected with the electrostatic capacity type displacement sensor 22 by the cable 23.

The earths of the electrostatic capacity conversion section 11 and the electrostatic capacity conversion section 21 are connected to one another by a lead.

The electrostatic capacity type displacement sensors 12 and 22 oppose to a rotation body 40 that is the measurement object, and are arranged at the position that shifts mutually as shown in FIG. 5 by 90°.

According to the rotor measurement apparatus 2, the electrostatic capacity conversion sections 11 and 21 apply to the electrostatic capacity type displacement sensors 12 and 22 carrier signals each having a sine wave of same frequency wherein the sum total of the phase becomes 0° (phases are different from one another by 180°), respectively.

Voltages E₁₀ and E₂₀ output from the electrostatic capacity conversion sections 11 and 21 are the voltages proportional to the distances between the rotation body 40 and the electrostatic capacity type displacement sensors 12 and 22, respectively. The change in the distance that depends on the shape of the rotation body 40 can be determined from the voltages E₁₀ and E₂₀. The same wave form signal with a different phase can be obtained from the voltages E₁₀ and E₂₀. The amplitude of a signal that extracts only the rotational primary component of the signal shows the eccentricity, and a signal that extracts the rotational secondary or more components show the peculiar shape to the rotation body. A difference between the maximum value and minimum value (peak-to-peak value) is the roundness. The phase computation is performed in view of the fact that the installation positions of the electrostatic capacity type displacement sensors 12 and 22 are mutually shifted by 90°, and the deformation direction of the rotation body 40, such as the eccentricity, can be computed.

Here, when the vibration component is included in the rotation body 40, the voltages E₁₀ and E₂₀ are not identical with one another in a wave form, and it is possible to analyze the vibration from these voltages E₁₀ and E₂₀. As an easy technique, the rotation body 40 is slowly rotated so that the vibration is not generated, and the eccentricity of the rotation body 40 and the shape of roundness are measured with the electrostatic capacity type displacement sensors 12 and 22, and the result is stored as standard shape in the device. Afterwards, a similar measurement is performed by usually rotating. The vibration component can be extracted by subtracting the standard shape subjected to the phase match from the measurement result. Computing the phase based on two data makes it possible to compute the vector in the direction of the vibration.

Moreover, voltages E₁₀ and E₂₀ are input to the oscilloscope 2_2, and Lissajou's wave is displayed on the screen of the oscilloscope 2_2, and, as a result, the eccentricity of the rotation body 40 is evaluated.

According to the rotor measurement apparatus 2 of the second embodiment, the eccentricity of the rotation body 40 is measured with two of the first electrostatic capacity type displacement sensor 10 and the second electrostatic capacity type displacement sensor 20. Thus, it is possible to measure the eccentricity of the rotation body 40 with greater stability as compared with the case of measurement of the eccentricity of the rotation body 40 with one electrostatic capacity type displacement sensor. Therefore, even if there occur impedances between the rotation body 40 and earths of the electrostatic capacity conversion sections 11 between 21, the carrier signals become mutually negative. As a result, no carrier currents flow from the electrostatic capacity conversion sections 11 and 12 to the impedance. Thus, the rotor measurement apparatus 2 is independent of the impedance between the rotation body 40 and earths of the electrostatic capacity conversion sections 11 and 12. Therefore, it is possible to measure the eccentricity of the rotation body 40 with greater stability.

In the event that the rotation body is measured with the conventional rotor measurement apparatus, there is a necessity to take via a brush and the like a conduction between the rotation body and the earths of two electrostatic capacity type displacement sensing devices. Therefore, there is a necessity to take measures and attention to the frictional wear of the brush and the loose connection of the brush. Further, there is a case where a ball bearing is used for the rotation axis, and conduction is taken with a jig that fixes the bearing. However, because the bearing doesn't guarantee necessarily electric conduction, the measurement result might become unstable. In addition, in a precision spindle such as air bearings, it is necessary to take conduction with the rotation body because there is no conduction between a bearing fixation section and a rotation section of the precision spindle such as the air bearings. It is difficult, however, to take conduction with the rotation body because it often rotates precisely in the precision spindle. Moreover, it is not few that it is not desired to touch it directly to the rotation body when conduction with the rotation body is taken. To the contrarily, according to the rotor measurement apparatus 2 of the second embodiment, there is no need to take conduction between the rotation body 40 and earths of the electrostatic capacity conversion sections 11 and 12. Therefore, it is possible to implement an easy measurement.

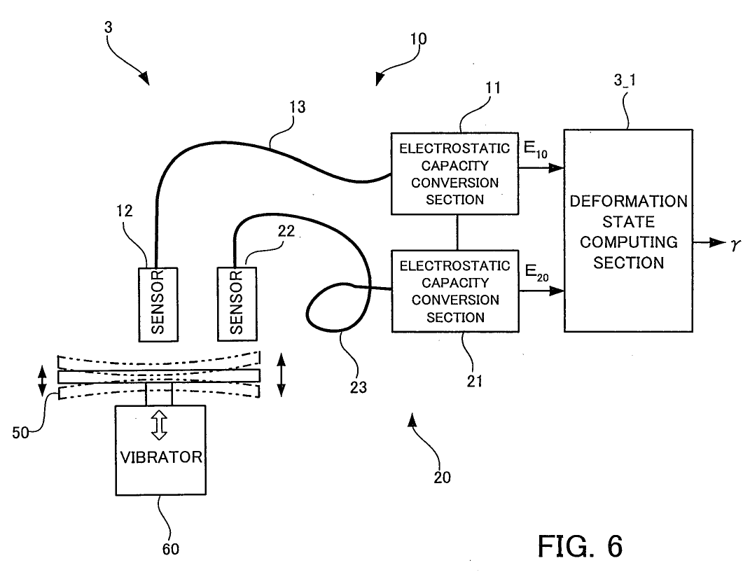

FIG. 6 is a schematic construction view of a vibration body measurement apparatus according to a third embodiment of a measurement apparatus of the present invention.

In FIG. 6, the same parts are denoted by the same reference numbers as those of the thickness measurement apparatus shown in FIG. 3.

A vibration body measurement apparatus 3 shown in FIG. 6 comprises the first electrostatic capacity type displacement sensing device 10, the second electrostatic capacity type displacement sensing device 20, and a deformation state computing section 3_1. The first electrostatic capacity type displacement sensing device 10 and the second electrostatic capacity type displacement sensing device 20 have electrostatic capacity type displacement sensors 12 and 22, respectively. The electrostatic capacity type displacement sensors 12 and 22 are arranged, on a surface side of a tabular vibration body 50 that is the measurement object, at a position apart from the surface by a prescribed distance away. The vibration body measurement apparatus 3 has a vibrator 60 for applying vibration to the vibration body 50.

Difference (E₂₀−E₁₀) of the measured voltage in the state without the vibration is stored in the deformation state computing section 3_1 as a standard state including an intrinsic geometry of the vibration body 50 and a physical state of a measurement system.

A difference between the difference (E₂₀−E₁₀) of the voltage in the vibrating state and the stored standard state indicates the deformation state. The difference signal is output in form of a signal γ. The deformation state of the vibration body 50 can be analyzed more in detail by moving the position of the electrostatic capacity type displacement sensor 22 and measuring a similar multipoint.

According to the vibration body measurement apparatus 3, the electrostatic capacity type displacement sensors 12 and 22 apply to the electrostatic capacity type displacement sensors 12 and 22, respectively, sine wave carrier signals each having the same frequency wherein the sum total of the phases becomes 0°. Therefore, even if there occur impedances between the vibration body 50 and earths of the electrostatic capacity conversion sections 11 between 21, the carrier signals become mutually negative. As a result, no carrier currents flow from the electrostatic capacity conversion sections 11 and 21 to the impedance. Thus, the vibration body measurement apparatus 3 is independent of the impedance between the vibration body 50 and earths of the electrostatic capacity conversion sections 11 and 21. Therefore, it is possible to measure the deformation of the vibration body 50 involved in vibration with stability.

According to the conventional vibration body measurement apparatus, if a thick lead is used to make it to strength that can endure vibrating when the lead is connected with the vibrating measurement object, it influences the behavior of the measurement object. On the other hand, if a thin lead is used, there is a possibility of an occurrence of breaking of wire. To the contrarily, according to the vibration body measurement apparatus 3 of the third embodiment, there is no need to take the conduction between the vibration body 50 and earths of the electrostatic capacity conversion sections 11 and 21. Therefore, it is possible to perform easy measurement.

Further, according to the vibration body measurement apparatus 3 of the third embodiment, it is possible to perform the change measurement of displacement with stability when the displacement of the same place is measured even in a case where the conductor that becomes the measurement object of the displacement measurement is covered with the insulator. The reason why the influence is able to be disregard is that a constant error margin is always included in the measurement result in the condition that thickness and the relative permittivity of the insulator are identical, and the amount of the change becomes the difference of the displacement values.

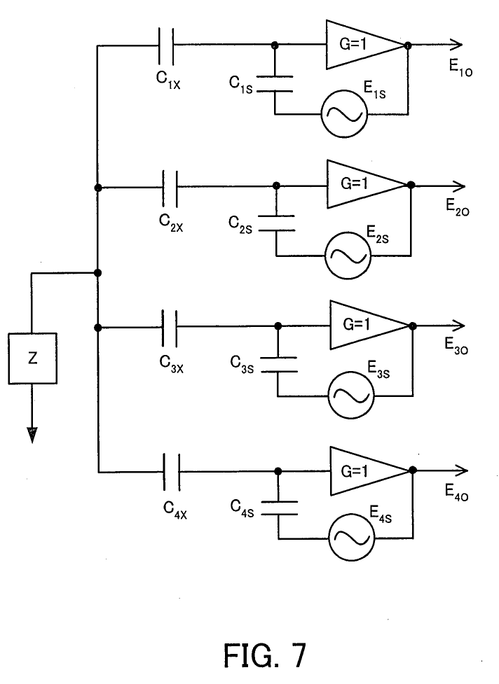

FIG. 7 is a view showing an equivalent circuit showing a thickness measurement apparatus according to a fourth embodiment of a measurement apparatus of the present invention.

Four electrostatic capacity type displacement sensing devices are prepared for in the thickness measurement apparatus according to the fourth embodiment, and the equivalent circuits of these four electrostatic capacity type displacement sensing devices are shown in FIG. 7 though it explained by the example of two electrostatic capacity type displacement sensing devices in the thickness measurement apparatus 1 shown in FIG. 3. The four electrostatic capacity type displacement sensing devices have four electrostatic capacity type displacement sensors (the 1st, the 2nd, the 3rd and 4th electrostatic capacity type displacement sensors), respectively.

While the thickness measurement apparatus according to the fourth embodiment is provided with two thickness computing sections corresponding to the electrostatic capacity type each of two displacement sensors of four electrostatic capacity type displacement sensors, the equivalent circuits in these two thickness computing sections is omitted in illustration in FIG. 7.

FIG. 7 shows an electric capacity C₁ₓ between the first electrostatic capacity type displacement sensor and a measurement object, an electric capacity C₂ₓ between the second electrostatic capacity type displacement sensor and a measurement object, an electric capacity C₃ₓ between the third electrostatic capacity type displacement sensor and a measurement object, and an electric capacity C₄ₓ between the fourth electrostatic capacity type displacement sensor and a measurement object. In FIG. 7, an impedance Z is inserted between the earth and the common node of the electric capacities C₁ₓ, C₂ₓ, C₃ₓ, and C₄ₓ.

Moreover, the equivalent circuit shows carrier signals E₁ₛ, E₂ₛ, E₃ₛ, and E₄ₛ of the 1st, the 2nd, the 3rd, and 4th electrostatic capacity type displacement sensors, electric capacities C₁ₓ, C₂ₓ, C₃ₓ, and C₄ₓ of a standard capacitor, and four amplifiers (both gain G=1).

Here, output voltage E₁₀ of the first electrostatic capacity type displacement sensor shown in FIG. 7 is expressed by the following expression.

$${E}_{1 O} = Z ( \frac{{E}_{1 S}}{{Z}_{1 S}} + \frac{{E}_{2 S}}{{Z}_{2 S}} + \frac{{E}_{3 S}}{{Z}_{3 S}} + \frac{{E}_{4 S}}{{Z}_{4 S}} ) + {d}_{1 X} \frac{{C}_{1 S} {E}_{1 S}}{ɛ {S}_{1 X}} \qquad ( 9 )$$

The carrier current from each electric capacity type displacement sensing device flows to the impedance Z, and it becomes an error margin of the voltage output from the first electrostatic capacity type displacement sensing device. It becomes an error margin similar as for the voltage output from the other three electrostatic capacity type displacement sensing devices. It indicates that the error margin of the output voltage grows when the number of use is increased.

According to the fourth embodiment, it is expressed by the following expression.

E_{2S}=−E_{1S}, Z_{2S}=Z_{1S} E_{4S}=−E_{3S}, Z_{4S}=Z_{3S} (10)

Thus, the following expression is obtained.

$$Z ( \frac{{E}_{1 S}}{{Z}_{1 S}} + \frac{{E}_{2 S}}{{Z}_{2 S}} + \frac{{E}_{3 S}}{{Z}_{3 S}} + \frac{{E}_{4 S}}{{Z}_{4 S}} ) = 0 \qquad ( 11 )$$

Accordingly, the following expression is obtained.

$${E}_{1 O} = {d}_{1 X} \frac{{C}_{1 S} {E}_{1 S}}{ɛ {S}_{1 X}} \qquad ( 12 )$$

Thus, the error margin related to the impedance Z is prevented from occurring in the output voltage. To the contrarily, according to the conventional technology, the current that flows to the impedance Z to the extent that the number is increased increases, and as a result, the error margin of the output voltage grows, too.

As mentioned above, according to the present invention, it is possible to provide a measurement apparatus and a measurement method capable of stably measuring the physical quantity involved in a measurement object.

While the present invention has been described with reference to the particular illustrative embodiments, it is not to be restricted by those embodiments but only by the appended claims. It is to be appreciated that those skilled in the art can change or modify the embodiments without departing from the scope and sprit of the present invention.

What is claimed is:

1. A measurement apparatus that measures a physical quantity involved in a measurement object in accordance with two or more electrostatic capacities determined by two or more electrostatic capacity type displacement sensing devices, where each of the two or more electrostatic capacity type displacement sensing devices has a measuring head to be arranged at a position opposed to the measurement object and determines an electrostatic capacity between the measurement object and the measuring head which electrostatic capacity changes according to a distance between the measurement object and the measuring head, and the measuring heads of the electrostatic capacity type displacement sensing devices are arranged opposing to the measurement object,
wherein the two or more electrostatic capacity type displacement sensing devices are mutually connected in their earths and apply to the measuring heads carrier signals each including a sinusoidal wave of a same frequency wherein a sum total of phases becomes 0°, respectively.

2. The measurement apparatus according to claim 1, wherein the measurement apparatus is a thickness measurement apparatus in which the measuring heads of two electrostatic capacity type displacement sensing devices are arranged opposing to one another, and the measurement object is disposed between both the measuring heads so that a thickness of the measurement object is measured in accordance with the two electrostatic capacities determined by the two electrostatic capacity type displacement sensing devices.

3. The measurement apparatus according to claim 1, wherein the measurement apparatus is a rotation body measurement apparatus in which the measuring heads of two or more electrostatic capacity type displacement sensing devices are arranged opposing to a rotation body that is the measurement object, and the physical quantity of the rotation body is measured in accordance with the two or more electrostatic capacities determined by the two or more electrostatic capacity type displacement sensing devices.

4. The measurement apparatus according to claim 1, wherein the measurement apparatus is a vibration body measurement apparatus in which the measuring heads of two or more electrostatic capacity type displacement sensing devices are arranged opposing to a vibration body that is the measurement object, and a vibration of the vibration body is measured in accordance with the two or more electrostatic capacities determined by the two or more electrostatic capacity type displacement sensing devices.

5. A measurement method of measuring physical quantity involved in a measurement object, the measurement method comprising the steps of:
preparing two or more electrostatic capacity type displacement sensing devices each of which has a measuring head that to be arranged at a position opposed to the measurement object, and which determine an electrostatic capacity between the measurement object and the measuring head which electrostatic capacity changes according to a distance between the measurement object and the measuring head;
arranging the measuring heads of the electrostatic capacity type displacement sensing devices as being opposed to the measurement object;
mutually connecting two or more electrostatic capacity type displacement sensing devices in their earths and applying to the measuring heads carrier signals each including a sinusoidal wave of a same frequency wherein a sum total of phases becomes 0°, respectively, so that electrostatic capacities are measured using the two or more electrostatic capacity type displacement sensing devices; and
determining a physical quantity involved in the measurement object in accordance with the two or more electrostatic capacities determined by the two or more electrostatic capacity type displacement sensing devices.

6. The measurement method according to claim 5, wherein the measurement method is a thickness measurement method in which the measuring heads of two electrostatic capacity type displacement sensing devices are arranged opposing to one another, and the measurement object is disposed between both the measuring heads so that a thickness of the measurement object is measured in accordance with the two electrostatic capacities determined by the two electrostatic capacity type displacement sensing devices.

7. The measurement method according to claim 5, wherein the measurement method is a rotation body measurement method in which the measuring heads of two or more electrostatic capacity type displacement sensing devices are arranged opposing to a rotation body that is the measurement object, and the physical quantity of the rotation body is measured in accordance with the two or more electrostatic capacities determined by the two or more electrostatic capacity type displacement sensing devices.

8. The measurement method according to claim 5, wherein the measurement method is a vibration body measurement method in which the measuring heads of two or more electrostatic capacity type displacement sensing devices are arranged opposing to a vibration body that is the measurement object, and a vibration of the vibration body is measured in accordance with the two or more electrostatic capacities determined by the two or more electrostatic capacity type displacement sensing devices.
